(19) United States
(12) Patent Application Publication
(10) Pub. No.: US 2019/0212864 A1
(43) Pub. Date: Jul. 11, 2019

(54) TOUCH PANEL

(71) Applicant: Sharp Kabushiki Kaisha, Sakai City (JP)

(72) Inventors: Yasuhiro SUGITA, Sakai City (JP); Jean MUGIRANEZA, Sakai City (JP); Kazutoshi KIDA, Sakai City (JP)

(21) Appl. No.: 16/211,364

(22) Filed: Dec. 6, 2018

(30) Foreign Application Priority Data
Jan. 9, 2018 (JP) 2018-001330

(51) Int. Cl. G06F 3/041; G06F 3/044; H01L 27/12

(52) U.S. Cl. CPC G06F 3/0416; H01L 27/1214; G06F 3/044

(57) ABSTRACT

Each transistor, which is provided for a corresponding sensor electrode, has a gate electrode, a source electrode connected to a power supply line, and a drain electrode connected to the sensor electrode.

### BACKGROUND

### 1. Field

The present disclosure relates to a touch panel.

### 2. Description of the Related Art

Examples of in-cell touch panels according to the related art are disclosed in Chelose Kim et al. “Advanced In-cell Touch Technology for Large Sized Liquid Crystal Displays” SID 2015 DIGEST, 2015 and “Technical Information: JDI's LCD Technology: Thin and Light Structure” (Japan Display Inc., (Online Search on Nov. 2, 2018, URL: http://www.j-display.com/technology/jdilcd/thin_light.html)).

In the touch panel according to the related art, since sensor electrodes are apart from a driver, wiring resistance and parasitic resistance of a charging line are large. Accordingly, it takes time to charge the sensor electrodes. As a result, there is a problem that the time constant is large.

It is desirable to realize a touch panel having a small time constant.

### SUMMARY

A touch panel according to an embodiment of the present disclosure includes a plurality of sensor electrodes, a plurality of sense lines, a first power supply line, a first power supply, and a plurality of first transistors. The sensor electrodes are arranged two-dimensionally. The sense lines are arranged to correspond to one or more of the plurality of sensor electrodes. The first power supply outputs a first voltage to the first power supply line. Each of the first transistors is provided for a corresponding one of the sensor electrodes and has a control electrode, a first conductive electrode connected to the first power supply line, and a second conductive electrode connected to the corresponding one of the sensor electrodes.

### BRIEF DESCRIPTION OF THE DRAWINGS

FIG. 1 is a diagram illustrating a configuration of a touch panel according to Embodiment 1;

FIG. 2 is a diagram illustrating an internal configuration of the touch panel according to Embodiment 1 in more detail;

FIG. 3 is a diagram for explaining charging of a sensor electrode and reading of electric charge from the sensor electrode in Embodiment 1;

FIG. 4 is a timing chart at the time of operation of the touch panel according to Embodiment 1;

FIG. 5 is a graph for explaining advantages according to Embodiment 1;

FIG. 6 is a diagram illustrating a configuration of a touch panel according to Embodiment 2;

FIG. 7 is a diagram illustrating an internal configuration of the touch panel according to Embodiment 2 in more detail;

FIG. 8 is a diagram for explaining charging of a sensor electrode and reading of electric charge from the sensor electrode in Embodiment 2;

FIG. 9 is a timing chart at the time of operation of the touch panel according to Embodiment 2;

FIG. 10 is a diagram illustrating a configuration of a touch panel according to Embodiment 3;

FIG. 11 is a diagram illustrating an internal configuration of the touch panel according to Embodiment 3 in more detail;

FIG. 12 is a diagram for explaining charging of a sensor electrode and reading of electric charge from the sensor electrode in Embodiment 2; and

FIG. 13 is a timing chart at the time of operation of the touch panel according to Embodiment 1.

### DESCRIPTION OF THE EMBODIMENTS

### Embodiment 1

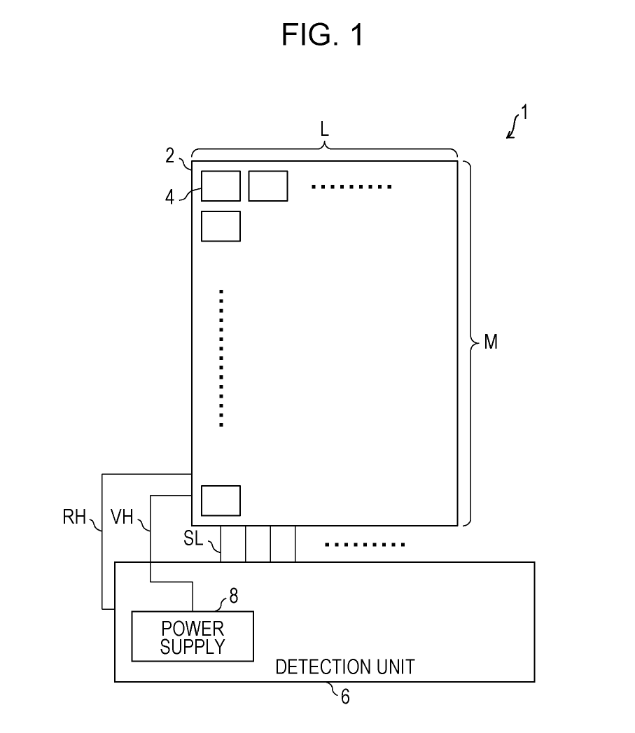

FIG. 1 is a diagram illustrating a configuration of a touch panel 1 according to Embodiment 1. As illustrated in the drawing, the touch panel 1 includes a touch detection region 2, a plurality of sensor electrodes 4, a detection unit 6, a power supply 8 (first power supply), a control line RH (first control line), a power supply line VH (first power supply line), and a plurality of sense lines SL.

The plurality of sensor electrodes 4 are arranged two-dimensionally in the touch detection region 2. In the present embodiment, the plurality of sensor electrodes 4 are arranged in a matrix. In FIG. 1, the touch panel 1 includes sensor electrodes 4 arranged in M rows (M is an integer of 2 or more)×L columns (L is an integer of 2 or more). The L sensor electrodes 4 are arranged for each row in the touch detection region 2, and the M sensor electrodes 4 are arranged for each column in the touch detection region 2.

The power supply line VH is provided in common to all the sensor electrodes 4. Each of the plurality of sense lines SL is arranged to correspond to one or more of the plurality of sensor electrodes 4.

The detection unit 6 is disposed outside the touch detection region 2 and opposes an end portion of the touch detection region 2. The detection unit 6 is a circuit for detecting pressing the touch detection region 2 by a user. The power supply 8 is disposed inside the detection unit 6. The present disclosure is not limited to this, and the power supply 8 may be disposed outside the detection unit 6. The power supply 8 outputs a voltage VH (first voltage), which is a voltage for charging the sensor electrodes, to the power supply line VH. As described above, in the present embodiment, the voltage or signal, which is supplied as an output to a certain line, may be referred to by the same name as the line.

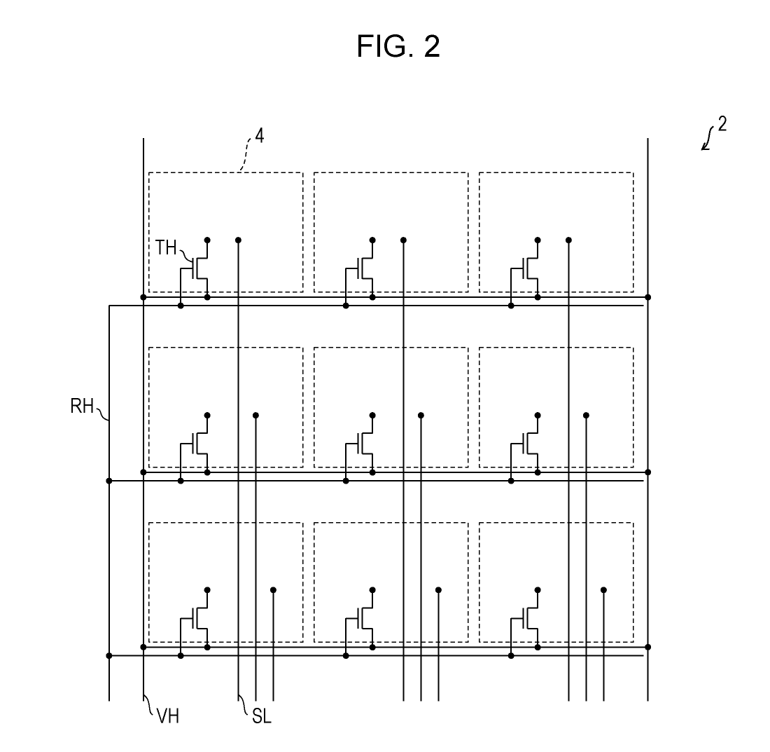

FIG. 2 is a diagram illustrating an internal configuration of the touch panel 1 according to Embodiment 1 in more detail. As illustrated in the drawing, the touch panel 1 further includes a plurality of transistors TH (first transistors) each of which is provided for a corresponding one of the sensor electrodes 4. Each transistor TH is a thin film transistor (TFT) having a gate electrode (control electrode), a source electrode (first conductive electrode), and a drain electrode (second conductive electrode). In the transistor TH provided in a certain sensor electrode 4, the gate electrode is connected to the control line RH, the source electrode is connected to the power supply line VH, and the drain electrode is connected to the sensor electrode 4. In other words, the gate electrodes of the plurality of transistors are connected to the control line RH in common. Thereby, in a case where the detection unit 6 outputs an ON-level control signal RH to the control line RH, all the transistors TH are turned on together. In a case where the detection unit 6 outputs an OFF-level control signal RH to the control line RH, all the transistors TH are turned off together. Consequently, in the touch panel 1, the number of control lines RH does not increase drastically (increases by two only) as compared with that in the related art.

In the present embodiment, outputting the ON-level control signal to the line may be expressed as “driving the line”.

In FIG. 2, for each of the sensor electrodes 4, a corresponding one of the sense lines SL is provided, and the sensor electrode 4 is connected to the corresponding sense line SL. Accordingly, the detection unit 6 is able to simultaneously and individually read the electric charges from the plurality of sensor electrodes 4. The number of the sense lines SL is equal to the number of the sensor electrodes 4 and is equal to L X M.

The detection unit 6 consistently causes the power supply 8 to continuously output the voltage VH to the power supply line VH. Accordingly, the power supply line VH is consistently charged with the voltage VH. In a case where the transistor TH is in off, the voltage VH is not supplied to the sensor electrode 4.

### Charging and Reading

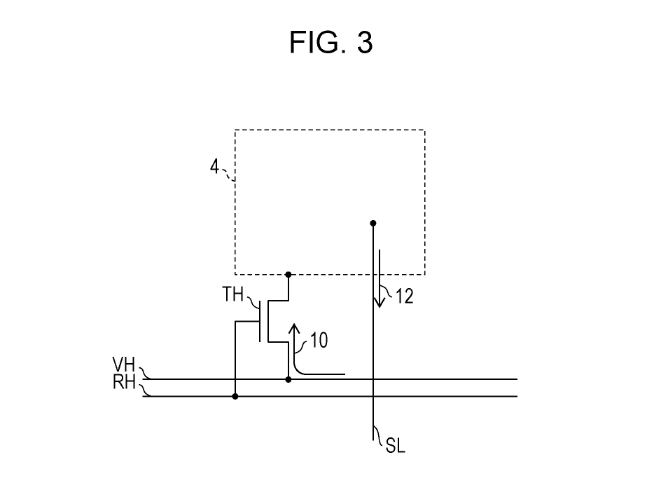

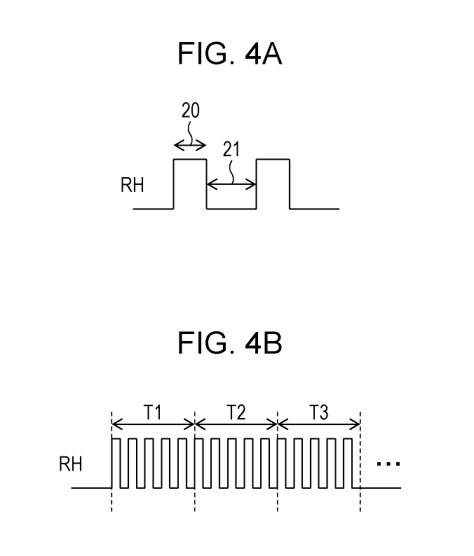

FIG. 3 is a diagram for explaining charging of a sensor electrode 4 and reading of electric charge from the sensor electrode in Embodiment 1. FIGS. 4A and 4B are timing charts at the time of operation of the touch panel 1 according to Embodiment 1.

As illustrated in FIG. 3, in the touch panel 1, the transistor TH is provided immediately below the sensor electrode 4. When the transistor TH is in off, the voltage VH is supplied in advance to the power supply line VH connected to the source electrode of the transistor TH. With such a configuration, the transistor TH substantially functions as a power supply capable of supplying the voltage VH.

As illustrated in FIG. 4A, in a charging period 20, the detection unit 6 outputs the ON-level (pulsed) control signal RH to the gate electrode of the transistor TH through the control line RH. Thereby, the transistor TH is turned on, and the voltage VH is immediately supplied to the sensor electrode 4 through the transistor TH, as indicated by arrow 10 in FIG. 3. In other words, the voltage VH is supplied from the transistor TH, which functions as a power supply, to the sensor electrode 4 through the supply of the control signal RH.

In a case where a conductive pointer such as a user's finger is in the vicinity of the sensor electrode 4, electric charge accumulates between the sensor electrode 4 and the pointer through the supply of the voltage VH to the sensor electrode 4. In the reading period 21 after the charging period 20, the detection unit 6 outputs the OFF-level control signal RH to the gate electrode of the transistor TH through the control line RH. Thereby, the transistor TH is turned off, and the detection unit 6 then reads the electric charge, which has accumulated between the sensor electrode 4 and the pointer, through the sense line SL connected to the sensor electrode 4 as indicated by arrow 12 in FIG. 3. The detection unit 6 detects the amount of electric charge in accordance with the read electric charge. Thus, one charging and reading operation is completed.

In FIG. 4B, the detection unit 6 averages the detected amounts of electric charge by charging the sensor electrode 4 and reading the electric charge a plurality of times at regular intervals. For example, in the period T1, the detection unit 6 charges the sensor electrode 4 five times and reads the electric charge five times, and averages the detected amounts of electric charge of the sensor electrode 4. The detection unit 6 also operates similarly in the period T2 and thereafter. With such a configuration, the touch panel 1 is able to increase the signal-to-noise ratio of the detected amount of electric charge. Therefore, the touch panel 1 is able to correctly detect the pressed position in the touch detection region 2.

### Advantages of Present Embodiment

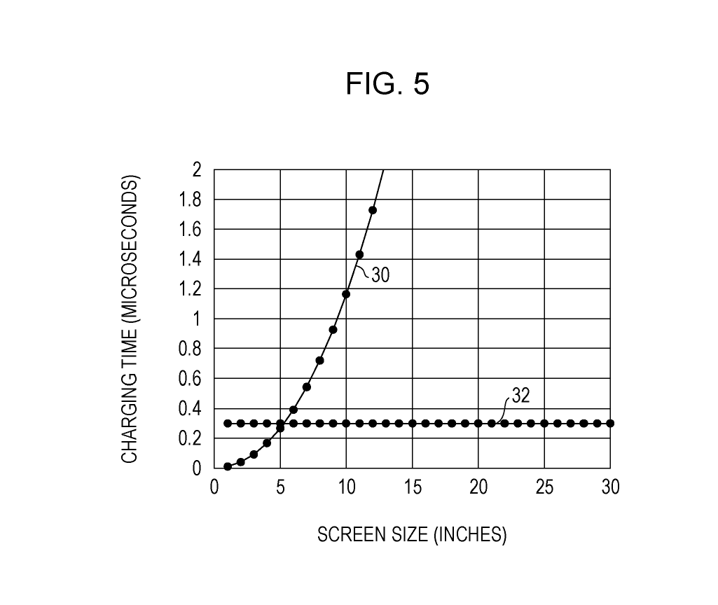

FIG. 5 is a graph for explaining advantages according to the present embodiment. In FIG. 5, the horizontal axis represents the screen size (inches) of the touch panel, and the vertical axis represents the charging time (microseconds) of the touch panel. The curve 30 indicates a relationship between the charging time and the screen size of the touch panel according to the related art. The straight line 32 indicates a relationship between the charging time and the screen size of the touch panel 1 according to the present embodiment. The charging time means a charging time of the sensor electrode. The screen size means a screen size of the touch panel.

In the touch panel according to the related art, sense lines are individually connected to respective sensor electrodes, and both charging of each sensor electrode and reading of electric charge from the sensor electrode are performed through the same sense line. Thereby, a charging time t_{charge} of the touch panel according to the related art is represented by Expression (1).

t_{charge}=(R_{trace}×C_{trace})/2+R_{trace}×C_{pad} Expression (1)

In Expression (1), R_{trace} is a wiring resistance of the sense line. C_{trace} is a wiring capacitance (parasitic capacitance) of the sense line. C_{pad} is a capacitance of the sensor electrode.

In the touch panel according to the related art, the sensor electrodes are connected to the power supply through the sense lines. The power supply is provided outside the touch detection region and is thus apart from the sensor electrodes. The larger the touch screen, the longer each sense line. Accordingly, the larger the touch screen, the larger the wiring resistance R_{trace} and the wiring capacity C_{trace}. As indicated by the curve 30 in FIG. 5, in the touch panel according to the related art, as the screen size increases, charging time t_{charge} increases exponentially. As a result, there is a problem that the performance of the touch panel deteriorates and it becomes difficult to increase the size of the screen of the touch panel.

On the other hand, in the touch panel 1 according to the present embodiment, the charging time t_{charge} of the touch panel 1 is represented by Expression (2).

t_{charge}=(R_{trace}×C_{trace})/2+(R_{trace}/M+R_{TFT})×C_{pad} Expression (2)

In Expression (2), R_{trace} is a wiring resistance of the power supply line VH. C_{trace} is a wiring capacitance (parasitic capacitance) of the power supply line VH. R_{TFT} is an on-resistance of the transistor TH. C_{pad} is a capacitance of the sensor electrode.

In the touch panel 1 according to the present embodiment, the power supply voltage VH is promptly provided to the sensor electrode 4 through the transistor TH disposed immediately below the sensor electrode 4. The transistor TH substantially functions as a power supply, and thus it can be considered that the length of the wiring between the gate electrode of the transistor TH and the sensor electrode 4 is substantially zero compared with the length of the power supply line VH. Accordingly, in the touch panel 1, it can be considered that the wiring resistance R_{trace}=0 and the wiring capacitance C_{trace}=0. Therefore, Expression (3) is derived from Expression (2).

t_{charge}=R_{TFT}×C_{pad} Expression (3)

As illustrated in Expression (3), the charging time t_{charge} of the touch panel 1 is a value obtained by multiplying the on-resistance R_{TFT} of the transistor TH by the parasitic capacitance C_{pad} of the sensor electrode 4. Both the on-resistance R_{TFT} and the parasitic capacitance C_{pad} are constant regardless of the screen size of the touch panel 1. In the touch panel 1, the wiring resistance R_{trace} and the wiring capacitance C_{trace} do not affect the charging time t_{charge}. Thus, the charging time t_{charge} can be reduced. Further, as indicated by the straight line 32 in FIG. 5, the charging time t_{charge} of the touch panel 1 can be made constant regardless of the screen size. Consequently, it is possible to improve the performance of the touch panel 1. Furthermore, the touch panel 1 can be provided with a large screen and high resolution. In addition, the touch panel 1 can be made compatible with an active pen.

### Embodiment 2

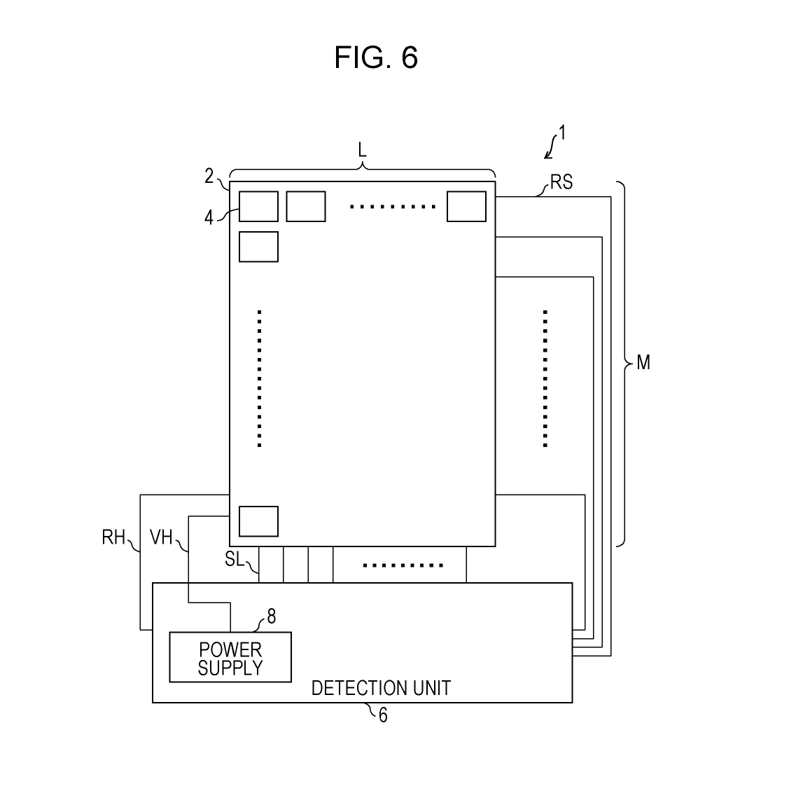

FIG. 6 is a diagram illustrating a configuration of a touch panel 1 according to Embodiment 2. As illustrated in the drawing, the touch panel 1 includes a touch detection region 2, a plurality of sensor electrodes 4, a detection unit 6, a power supply 8, a control line RH, a power supply line VH, a plurality of sense lines SL, and a plurality of control lines RS (second control lines).

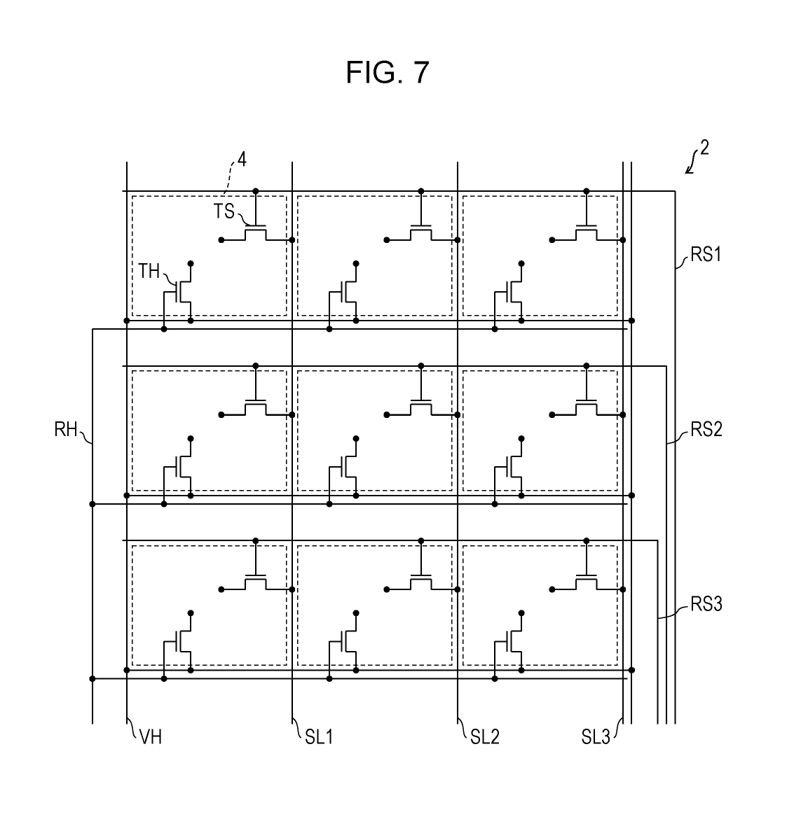

FIG. 7 is a diagram illustrating an internal configuration of the touch panel 1 according to Embodiment 2 in more detail. As illustrated in the drawing, the touch panel 1 further includes a plurality of transistors TH and a plurality of transistors TS (second transistors). Each transistor TH is provided for a corresponding one of the sensor electrodes 4. Each transistor TS is provided for a corresponding one of the sensor electrodes 4.

The arrangement and the connection form of the control line RH and the plurality of transistors TH are the same as those in Embodiment 1.

Each of the plurality of control lines RS is provided for a corresponding row of the sensor electrodes 4. In other words, the plurality of control lines RS include M control lines RS1 to RSM respectively arranged in the first to Mth rows in the touch detection region 2.

Each of the plurality of sense lines SL is provided for a corresponding column of the sensor electrodes 4. In other words, the plurality of sense lines SL include L sense lines SL1 to SLL respectively arranged in the first to Lth columns in the touch detection region 2.

Each of the plurality of transistors TS is a thin film transistor (TFT) having a gate electrode (control electrode), a source electrode (first conductive electrode), and a drain electrode (second conductive electrode). In the transistor TS provided in a certain sensor electrode 4, the gate electrode is connected to the control line RS corresponding to the sensor electrode 4, the source electrode is connected to the sense line SL corresponding to the sensor electrode 4, and the drain electrode is connected to the corresponding sensor electrode 4. In other words, the gate electrodes of the transistors TS in one row are connected in common to the control line RS, which is disposed in the same row as these transistors TS. Further, the drain electrodes of the transistors TS in one column are connected in common to the sense line SL, which is disposed in the same column as these transistors TS.

In FIG. 7, for example, the gate electrodes of the transistors TS arranged in the first row are connected in common to the control line RS1, which is disposed in the first row. With such a configuration, the detection unit 6 is able to simultaneously control ON or OFF of each of the transistors TS arranged in the first row. It is the same for the transistors TS in the second and subsequent rows. In FIG. 7, for example, the drain electrodes of the transistors TS arranged in the first column are connected in common to the sense line SL1, which is disposed in the first column. With such a configuration, electric charges can be individually read from the sensor electrodes 4, which are arranged in the first column, through the common sense line SL1.

### Charging and Reading

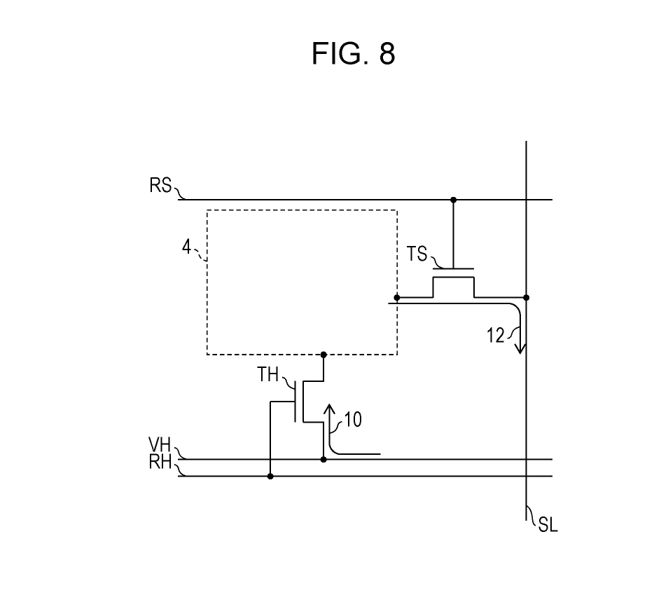

FIG. 8 is a diagram for explaining charging of the sensor electrode 4 and reading of electric charge from the sensor electrode 4 in Embodiment 2.

In the present embodiment, the detection unit 6 outputs an ON-level (pulsed) control signal RH to the gate electrode of the transistor TH through the control line RH. Thereby, the transistor TH is turned on, and the voltage VH is immediately supplied to the sensor electrode 4 through the transistor TH, as indicated by arrow 10 in FIG. 8. This point is the same as that of Embodiment 1. In the present embodiment, after outputting the control signal RH, the detection unit 6 outputs the ON-level control signal RS to the gate electrode of the transistor TS through the control line RS. Thereby, the transistor TS is turned on, and the detection unit 6 then reads the electric charge, which has accumulated between the sensor electrode 4 and the pointer, through the transistor TS connected to the sensor electrode 4 and the sense line SL, as indicated by arrow 12 in FIG. 8.

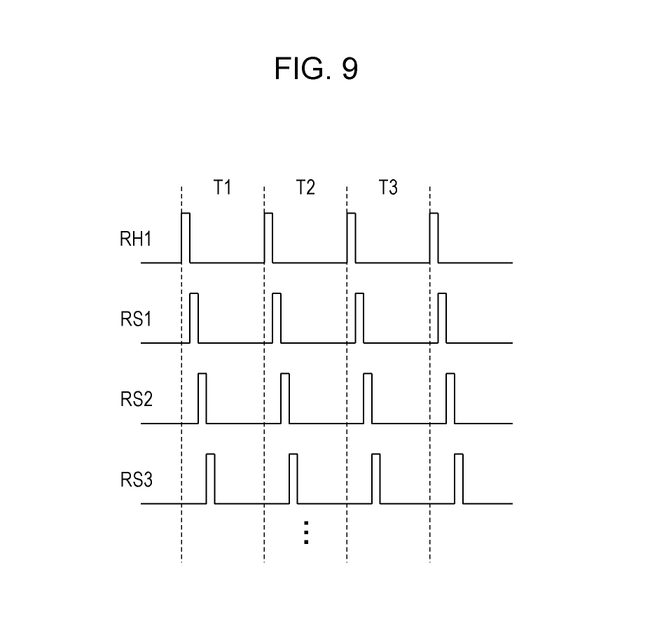

FIG. 9 is a timing chart at the time of operation of the touch panel 1 according to Embodiment 2. In the present embodiment, the detection unit 6 simultaneously charges all the sensor electrodes 4 as in Embodiment 1. Thereafter, in a certain period, the detection unit 6 simultaneously reads the electric charges of the sensor electrodes 4 in one row through the sense lines SL1 to SLL on a row-by-row basis.

As illustrated in FIG. 9, at the beginning of the period T1, the detection unit 6 outputs the pulsed ON-level control signal RH to the control line RH. Thereby, all the sensor electrodes 4 are simultaneously charged as indicated by an arrow 10 in FIG. 8. At this point in time, since the transistor TS is in off, electric charge is not read out. In a case where the control signal RH returns to the OFF level, charging of the sensor electrode 4 is completed.

After outputting the pulsed ON-level control signal RH, the detection unit 6 outputs the pulsed ON-level control signal RS to the gate electrodes of the L transistors TS in the first row through the control line RS1. With such a configuration, the transistors TS in the first row are simultaneously turned on, and therefore the detection unit 6 reads electric charges from the L sensor electrodes 4 arranged in the first row through the sense lines SL1 to SLL. Next, the detection unit 6 outputs the pulsed ON-level control signal RS to the gate electrodes of the L transistors TS in the second row through the control line RS2. With such a configuration, the transistors TS in the second row are simultaneously turned on, and therefore the detection unit 6 reads electric charges from the L sensor electrodes 4 arranged in the second row through the sense lines SL1 to SLL. It is the same for the third to Mth lines. Thus, in the period T1, reading of the electric charges from all the sensor electrodes 4 is completed.

In each period after the period T1, the detection unit 6 operates in a manner similar to that in the period T1. Consequently, the detection unit 6 is able to read electric charges from all the sensor electrodes 4 arranged in the touch detection region 2 for each period.

### Advantages of Present Embodiment

In the present embodiment, charging of each sensor electrode 4 with the voltage VH is performed by each transistor TH immediately below the sensor electrode 4 as in Embodiment 1. Thereby, as in Embodiment 1, the time constant can be reduced, and the time constant of the touch panel 1 can be made constant regardless of the screen size. Consequently, it is possible to improve the performance of the touch panel 1. Furthermore, the touch panel 1 can be provided with a large screen and high resolution. In addition, the touch panel 1 can be made compatible with an active pen.

In the present embodiment, the sense line SL is provided for a corresponding column of the sensor electrodes 4. Therefore, the number of sense lines SL is L. On the other hand, in the touch panel according to the related art, since each sensor electrode is provided for with a corresponding sense line, the number of sense lines is equal to L×M. As described above, in the touch panel 1 according to the present embodiment, the total number of the sense lines SL can be greatly reduced as compared with the touch panel according to the related art. In addition, the total amount of the wiring resistance of the sense lines SL in the touch detection region 2 can be greatly reduced. Therefore, it is possible to obtain the following advantages: it becomes easy to mount the terminal portion on the touch panel 1; and a general-purpose touch panel controller IC can be used in the touch panel 1.

### Embodiment 3

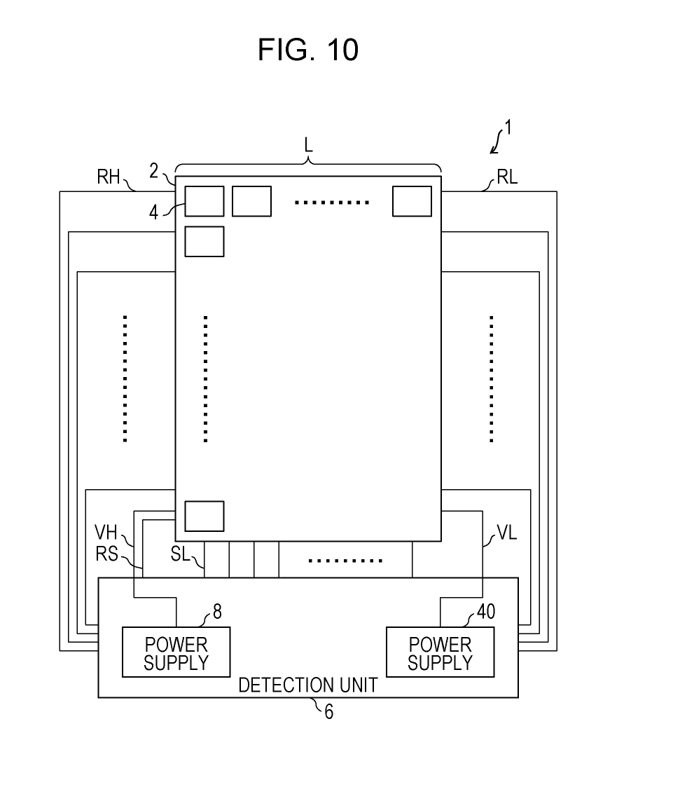

FIG. 10 is a diagram illustrating a configuration of a touch panel 1 according to Embodiment 3. As illustrated in the drawing, the touch panel 1 according to the present embodiment includes a touch detection region 2, a plurality of sensor electrodes 4, a detection unit 6, a power supply 8, a power supply 40 (second power supply), a plurality of control lines RH, a power supply line VH, a plurality of control lines RL (third control line), a power supply line VL (second power supply line), a plurality of sense lines SL, and a control line RS.

The power supply line VL is provided in common to all the sensor electrodes 4. The power supply 40 outputs a voltage VL (second voltage), which is for charging the sensor electrodes 4, to the power supply line VL. The voltage VL is different from a voltage VH which is output from the power supply line VH. For example, in a case where the voltage VH is a positive voltage +V, the voltage VL is a negative voltage −V. For example, in a case where the voltage VH is a high level voltage, the voltage VL is a low level voltage.

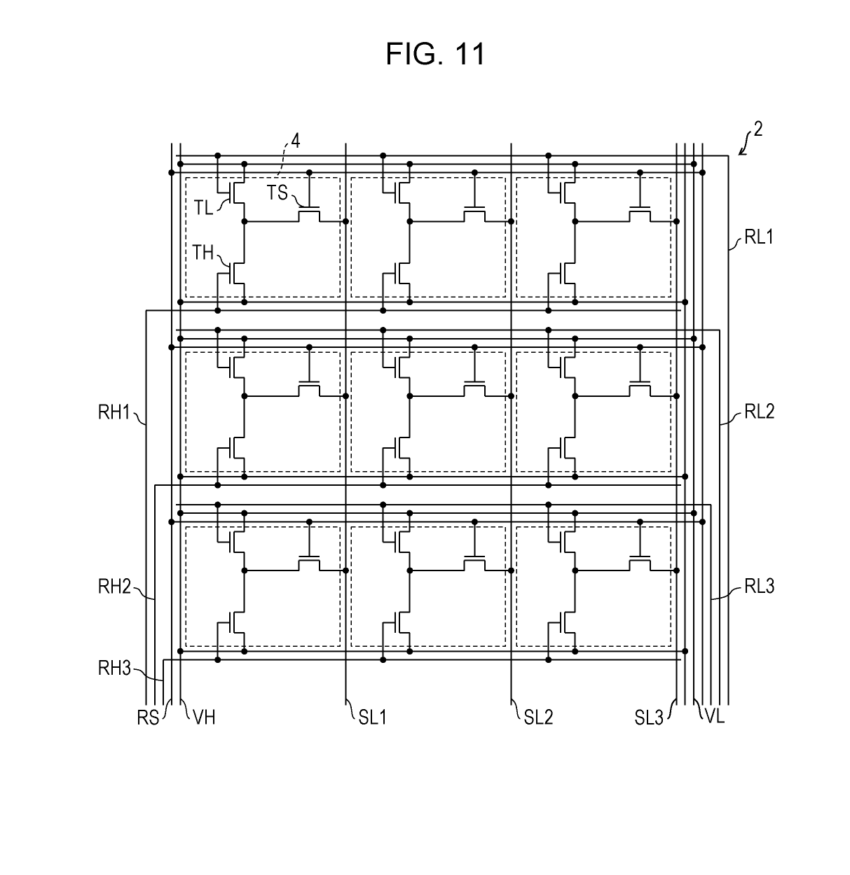

FIG. 11 is a diagram illustrating an internal configuration of the touch panel 1 according to Embodiment 3 in more detail. As illustrated in the drawing, the touch panel 1 includes a plurality of transistors TH, a plurality of transistors TL (third transistor), and a plurality of transistors TS. Each of the transistors TH is provided for a corresponding one of the sensor electrodes 4. Each of the transistors TL (third transistors) is provided for a corresponding one of the sensor electrodes 4. Each of the transistors TS is provided for a corresponding one of the sensor electrodes 4.

Each of the plurality of control lines RH is provided for a corresponding row of the sensor electrodes 4. In other words, the plurality of control lines RH include M control lines RH1 to RHM respectively arranged in the first to Mth rows in the touch detection region 2.

Each of the plurality of control lines RL is provided for a corresponding row of the sensor electrodes 4. In other words, the plurality of control lines RL include M control lines RL1 to RLM respectively arranged in the first to Mth rows in the touch detection region 2.

The control line RS is provided in common to all the sensor electrodes 4.

Each of the plurality of sense lines SL is provided for a corresponding column of the sensor electrodes 4. In other words, the plurality of sense lines SL include L sense lines SL1 to SLL respectively arranged in the first to Lth columns in the touch detection region 2.

In the transistor TH provided in a certain sensor electrode 4, the gate electrode is connected to the control line RH corresponding to the sensor electrode 4, the source electrode is connected to the power supply line VH, and the drain electrode is connected to the sensor electrode 4. In other words, the gate electrodes of the transistors TH in one row are connected in common to the control line RH, which is disposed in the same row as these transistors TH. In FIG. 11, the gate electrodes of the transistors TH arranged in the first row are connected in common to the control line RH1, which is disposed in the first row. With such a configuration, the detection unit 6 is able to simultaneously control ON or OFF of each of the transistors TH arranged in the first row. Therefore, the sensor electrodes 4 arranged in the first row are simultaneously charged with the voltage VH. It is the same for the transistors TH in the second and subsequent rows.

Each of the transistors TL is a thin film transistor (TFT) having a gate electrode, a source electrode, and a drain electrode. In the transistor TL provided in a certain sensor electrode 4, the gate electrode is connected to the control line RL corresponding to the sensor electrode 4, the source electrode is connected to the power supply line VL, and the drain electrode is connected to the sensor electrode 4. In other words, the gate electrodes of the transistors TL are connected in common to the control line RL, which is disposed in the same row as the transistors TL. In FIG. 11, the gate electrodes of the transistors TL arranged in the first row are connected in common to the control line RL1, which is disposed in the first row. With such a configuration, the detection unit 6 is able to simultaneously control ON or OFF of each of the transistors TL arranged in the first row. Therefore, the sensor electrodes 4 arranged in the first row are simultaneously charged with the voltage VL. It is the same for the transistors TL in the second and subsequent rows.

In a transistor TS provided in a certain sensor electrode 4, the gate electrode is connected to the control line RS, the source electrode is connected to the sensor electrode 4, and the drain electrode is connected to the sense line SL corresponding to the sensor electrode 4. In other words, the gate electrodes of all the transistors TS are connected to the same control line RS in common, and the drain electrodes of the transistors TS are connected in common to the sense line SL, which is disposed in the same row as the transistors TS. In FIG. 11, the drain electrodes of the transistors TS arranged in the first column are connected in common to the control line SL1, which is disposed in the first column. With such a configuration, the detection unit 6 is able to simultaneously read the electric charges from the sensor electrodes 4 arranged in the first column through the common control line SL1. Similarly, the detection unit 6 is able to simultaneously read the electric charges from the sensor electrodes 4, which are arranged in each column of the second and subsequent columns, through the corresponding sense line SL.

As illustrated in FIG. 11, in the touch panel 1, the transistor TL is provided immediately below the sensor electrode 4. When the transistor TL is in off, the voltage VL is supplied in advance from the power supply 40 to the power supply line VL connected to the source electrode of the transistor TL. With such a configuration, the transistor TL substantially functions as a power supply capable of supplying the voltage VL.

### Charging and Reading

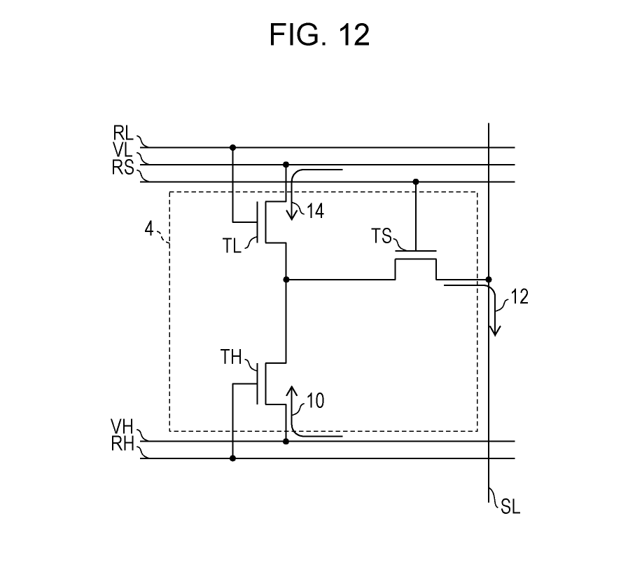

FIG. 12 is a diagram for explaining charging of the sensor electrode 4 and reading of electric charge from the sensor electrode 4 in Embodiment 3.

In the present embodiment, the detection unit 6 charges the sensor electrode 4 with either the voltage VH or the voltage VL. In a case where the sensor electrode 4 is charged with the voltage VH, the detection unit 6 outputs an ON-level (pulsed) control signal RH to the control line RH and outputs an OFF-level control signal RL to the control line RL. Then, the transistor TH is turned on, and the transistor TL is turned off. As a result, the voltage VH is immediately supplied to the sensor electrode 4 through the transistor TH as indicated by an arrow 10. In a case where the sensor electrode 4 is charged with the voltage VL, the detection unit 6 outputs an OFF-level control signal RH to the control line RH and outputs an ON-level (pulsed) control signal RL to the control line RL. Then, the transistor TH is turned off, and the transistor TL is turned on. As a result, the voltage VL is immediately supplied to the sensor electrode 4 through the transistor TL as indicated by an arrow 14. In other words, the voltage VL is supplied from the transistor TL, which functions as a power supply, to the sensor electrode 4 through the supply of the control signal RL.

After the sensor electrode 4 is charged, the detection unit 6 outputs an ON-level control signal RS to the control line RS. Thereby, the transistor TS is turned on, and the detection unit 6 then reads the electric charge, which has accumulated between the sensor electrode 4 and the pointer, through the transistor TS connected to the sensor electrode 4 and the sense line SL, as indicated by arrow 12 in FIG. 12.

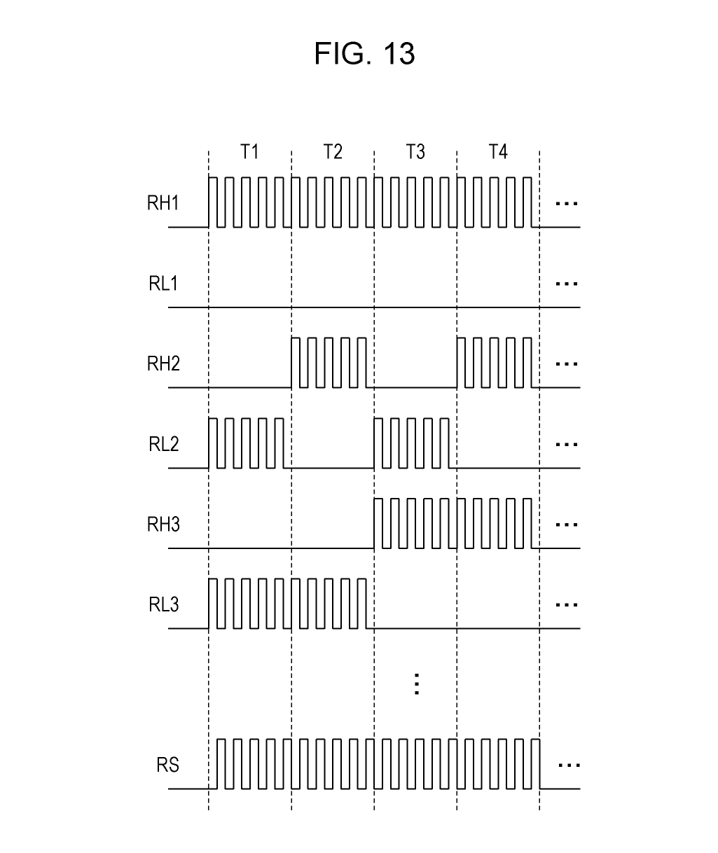

FIG. 13 is a timing chart at the time of operation of the touch panel 1 according to Embodiment 3. In the present embodiment, the detection unit 6 simultaneously charges the sensor electrodes 4 in one row with either the voltage VH or the voltage VL on a row-by-row basis. Thereafter, the detection unit 6 simultaneously reads the electric charges of the sensor electrodes 4 in one row through the sense lines SL1 to SLL. As described above, in the present embodiment, the detection unit 6 simultaneously reads the electric charges from all the sensor electrodes 4 through one reading operation. Further, the detection unit 6 repeats the simultaneous reading of all the electric charges a predetermined number of times while changing the pattern of charging the sensor electrodes 4 with the voltage VH or the voltage VL. Then, by analyzing a result of the reading performed the predetermined number of times, it is possible to calculate each amount of electric charge in each sensor electrode 4.

Specifically, first, code sequences di=(di1, di2, . . . , diN) (i=1, . . . , M) having code lengths of N (N is an integer larger than M) are prepared. The code sequences are each constituted by +1 and −1 and are orthogonal to one another. Here, the fact that “code sequences di=(di1, di2, . . . , diN) (i=1, . . . , M) having code lengths of N are orthogonal to one another” means that the code sequences di satisfy the following condition.

$$\begin{matrix}di \cdot dk = {\sum }_{j = 1}^{N} dij \times dkj \\ = N \times δ ik\end{matrix} \\ Here , \\ δ ik = 1 if i = k \\ δ ik = 0 if i \neq k \qquad Numerical Expression 1$$

Specific examples of the code sequences di are disclosed in Japanese Patent No. 4927216. The detection unit 6 drives M control lines RH1 to RHM and M control lines RL1 to RLM in parallel such that the voltage VH is applied to the sensor electrodes 4 in a case of +1 and the voltage VL is applied to the sensor electrodes 4 in a case of −1 in accordance with the code sequences di. With such a configuration, electric charge corresponding to the voltage VH or the voltage VL supplied to each sensor electrode 4 is accumulated in the sensor electrode 4 in accordance with each element (+1 or −1) of the code sequence. After the sensor electrode 4 is charged, the detection unit 6 drives the control line RS, thereby adding up the electric charges accumulated in the sensor electrodes 4, which are connected to the same sense line SL, along the same sense line SL, for each sense line SL. The detection unit 6 simultaneously reads the added electric charge for each sense line SL.

The detection unit 6 performs the charging of the sensor electrodes 4 and the reading of the electric charges N times in total in accordance with the code sequences di. As a result, the output sequence vectors sj=(sj1, sj2, . . . , SjN) (j=1, . . . , L) are obtained. The detection unit 6 estimates the capacitance values of the M sensor electrodes 4 each corresponding to the jth sense line SL in accordance with the inner product operations of the obtained output sequence vectors sj and the code sequences di.

In the example of FIG. 13, the detection unit 6 determines the patterns of driving the control lines RH1 to RHM and the control lines RL1 to RLM in accordance with di1 in the period T1. Specifically, the detection unit 6 drives the control line RH1 and does not drive the control line RL1 in the period T1. Thereby, each sensor electrode 4 in the first row is charged with the voltage VH. In the period T1, the detection unit 6 does not drive the control line RH2 and drives the control line RL2. Thereby, each sensor electrode 4 in the second row is charged with the voltage VL. In the period T1, the detection unit 6 does not drive the control line RH3 and drives the control line RL3. Thereby, each sensor electrode 4 in the second row is charged with the voltage VL. In the period T1, the detection unit 6 charges each sensor electrode 4 with the voltage VH or VL, and then drives the control line RS. As a result, the outputs sj1 are simultaneously obtained through the respective sense lines SLj. The sensor electrode 4 obtains five outputs sj1 by performing these operations five times in total in the same period T1, and calculates the average value of these outputs sj1.

In the example of FIG. 13, the detection unit 6 determines the patterns of driving the control lines RH1 to RHM and the control lines RL1 to RLM in accordance with dig in the period T2. Specifically, the detection unit 6 drives the control line RH1 and does not drive the control line RL1 in the period T2. Thereby, each sensor electrode 4 in the first row is charged with the voltage VH. In the period T2, the detection unit 6 drives the control line RH2 and does not drive the control line RL2. Thereby, each sensor electrode 4 in the second row is charged with the voltage VH. In the period T2, the detection unit 6 does not drive the control line RH3 and drives control line RL3. Thereby, each sensor electrode 4 in the second row is charged with the voltage VL. In the period T2, the detection unit 6 charges each sensor electrode 4 with the voltage VH or VL, and then drives the control line RS. As a result, the outputs sj2 are simultaneously obtained through the respective sense lines SLj. The sensor electrode 4 obtains five outputs sj2 by performing these operations five times in total in the same period T2, and calculates the average value of these outputs sj2.

The detection unit 6 operates similarly in the period from the period T3 to the period TN, thereby obtaining the output sequence vectors sj.

### Advantages of Present Embodiment

In the present embodiment, charging of each sensor electrode 4 with the voltage VH is performed by each transistor TH immediately below the sensor electrode 4 as in Embodiment 1. Further, charging of each sensor electrode 4 with the voltage VL is performed by each transistor TL immediately below the sensor electrode 4. Thereby, it possible to reduce the time constant of the touch panel 1 even in a case where the sensor electrode 4 is charged with either the voltage VH or the voltage VL. In addition, the time constant can be made constant regardless of the screen size. Consequently, it is possible to improve the performance of the touch panel 1. Furthermore, the touch panel 1 can be provided with a large screen and high resolution. In addition, the touch panel 1 can be made compatible with an active pen.

In the above-mentioned driving method, the driving method disclosed in Japanese Patent No. 4927216 is applied to the touch panel 1 of the present embodiment. Therefore, according to the present embodiment, similarly to Japanese Patent No. 4927216, it is possible to realize a touch panel 1 that has high detection accuracy and high resolution and that is capable of performing high speed operation.

In the touch panel 1 according to Embodiment 2, in a case where data is read N times from each sensor electrode 4, it is desired to sequentially perform reading for each row. Thus, the time for performing data reading N times is represented by the time of one reading operation X the number of rows X N. On the other hand, in the touch panel according to Embodiment 3, in a case where data is read N times from each sensor electrode 4 as in Embodiment 2, reading can be performed at once on the entire screen. Thus, the time for performing data reading N times is represented by the time of one reading operation×N. In this manner, the touch panel 1 according to Embodiment 3 is able to complete data reading at a higher speed than the touch panel 1 according to Embodiment 2. Further, as the number of rows of the touch panel 1 increases, this advantage becomes more effective. Therefore, according to Embodiment 3, it is possible to drive the touch panel 1 having the same performance as that of Embodiment 2 at a higher speed as compared with Embodiment 2.

### CONCLUSION

Aspect 1: A touch panel including: a plurality of sensor electrodes arranged two-dimensionally; a plurality of sense lines arranged to correspond to one or more of the plurality of sensor electrodes; a first power supply line; a first power supply that outputs a first voltage to the first power supply line; and a plurality of first transistors each of which is provided for a corresponding one of the sensor electrodes and has a control electrode, a first conductive electrode connected to the first power supply line, and a second conductive electrode connected to the corresponding one of the sensor electrodes.

Aspect 2: The touch panel according to Aspect 1, further including a first control line, in which the control electrode of each of the plurality of first transistors is connected to the first control line.

Aspect 3: The touch panel according to Aspect 2, in which for each of the sensor electrodes, a corresponding one of the sense lines is provided, and each of the sensor electrodes is connected to the corresponding one of the sense lines.

Aspect 4: The touch panel according to Aspect 2, further including: a plurality of second control lines each of which is provided for a corresponding row of the sensor electrodes; and a plurality of second transistors each of which is provided for a corresponding one of the sensor electrodes and has a control electrode connected to one of the second control lines which corresponds to the sensor electrode, a first conductive electrode connected to one of the sense lines which corresponds to the sensor electrode, and a second conductive electrode connected to the sensor electrode, in which for each column of the sensor electrodes, a corresponding one of the sense lines is provided.

Aspect 5: The touch panel according to Aspect 1, further including a plurality of first control lines each of which is provided for a corresponding row of the sensor electrodes, in which the control electrode of each of the first transistors is connected to one of the first control lines which corresponds to the sensor electrode for which the control electrode is provided.

Aspect 6: The touch panel according to Aspect 5, further including: a second control line; a plurality of second transistors each of which is provided for a corresponding one of the sensor electrodes and has a control electrode connected to the second control line, a first conductive electrode connected to one of the sense lines which corresponds to the sensor electrode, and a second conductive electrode connected to the sensor electrode; and a plurality of third control lines each of which is provided for a corresponding row of the sensor electrodes, in which for each column of the sensor electrodes, a corresponding one of the sense lines is provided.

Aspect 7: The touch panel according to Aspect 6, further including: a second power supply line; a second power supply that outputs to the second power supply line a second voltage different from the first voltage; and a plurality of third transistors each of which is provided for a corresponding one of the sensor electrodes and has a control electrode connected to one of the third control lines which corresponds to the sensor electrode, a first conductive electrode connected to the second power supply line, and a second conductive electrode connected to the sensor electrode.

The present disclosure is not limited to the above-mentioned embodiments, and may be modified into various forms without departing from the technical scope of claims. The technical scope of the present disclosure also involves embodiments obtained by appropriately combining technical means disclosed in different embodiments. By combining technical means disclosed in the embodiments, new technical features may be formed.

The present disclosure contains subject matter related to that disclosed in Japanese Priority Patent Application JP 2018-001330 filed in the Japan Patent Office on Jan. 9, 2018, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A touch panel comprising:
a plurality of sensor electrodes arranged two-dimensionally;
a plurality of sense lines arranged to correspond to one or more of the plurality of sensor electrodes;
a first power supply line;
a first power supply that outputs a first voltage to the first power supply line; and
a plurality of first transistors each of which is provided for a corresponding one of the sensor electrodes and has a control electrode, a first conductive electrode connected to the first power supply line, and a second conductive electrode connected to the corresponding one of the sensor electrodes.

2. The touch panel according to claim 1, further comprising a first control line, wherein
the control electrode of each of the plurality of first transistors is connected to the first control line.

3. The touch panel according to claim 2, wherein
for each of the sensor electrodes, a corresponding one of the sense lines is provided, and
each of the sensor electrodes is connected to the corresponding one of the sense lines.

4. The touch panel according to claim 2, further comprising:
a plurality of second control lines each of which is provided for a corresponding row of the sensor electrodes; and
a plurality of second transistors each of which is provided for a corresponding one of the sensor electrodes and has a control electrode connected to one of the second control lines which corresponds to the sensor electrode, a first conductive electrode connected to one of the sense lines which corresponds to the sensor electrode, and a second conductive electrode connected to the sensor electrode, wherein
for each column of the sensor electrodes, a corresponding one of the sense lines is provided.

5. The touch panel according to claim 1, further comprising a plurality of first control lines each of which is provided for a corresponding row of the sensor electrodes, wherein
the control electrode of each of the first transistors is connected to one of the first control lines which corresponds to the sensor electrode for which the control electrode is provided.

6. The touch panel according to claim 5, further comprising:
a second control line;
a plurality of second transistors each of which is provided for a corresponding one of the sensor electrodes and has a control electrode connected to the second control line, a first conductive electrode connected to one of the sense lines which corresponds to the sensor electrode, and a second conductive electrode connected to the sensor electrode; and
a plurality of third control lines each of which is provided for a corresponding row of the sensor electrodes, wherein
for each column of the sensor electrodes, a corresponding one of the sense lines is provided.

7. The touch panel according to claim 6, further comprising:
a second power supply line;
a second power supply that outputs to the second power supply line a second voltage different from the first voltage; and
a plurality of third transistors each of which is provided for a corresponding one of the sensor electrodes and has a control electrode connected to one of the third control lines which corresponds to the sensor electrode, a first conductive electrode connected to the second power supply line, and a second conductive electrode connected to the sensor electrode.
